(19) United States
(12) Patent Application Publication
(10) Pub. No.: US 2022/0140146 A1
(43) Pub. Date: May 5, 2022

(54) FERROELECTRIC DEVICES ENHANCED WITH INTERFACE SWITCHING MODULATION

(71) Applicant: Applied Materials, Inc., Santa Clara, CA (US)

(72) Inventor: Milan Pesic, San Jose, CA (US)

(73) Assignee: Applied Materials, Inc., Santa Clara, CA (US)

(21) Appl. No.: 17/084,953

(22) Filed: Oct. 30, 2020

(51) Int. Cl. H01L 29/78; H01L 21/28; G11C 11/22; H01L 27/11585

(52) U.S. Cl. CPC H01L 29/78391; H01L 27/11585; G11C 11/223; H01L 29/40111

(57) ABSTRACT

An enhanced ferroelectric transistor may include Interface switching modulation (ISM) layers along with a ferroelectric layer in the gate of the transistor to increase a memory window while maintaining relatively low operating voltages. The enhanced ferroelectric transistor may be implemented as a memory device storing more than two bits of information in each memory cell. An enhanced ferroelectric tunnel junction device may include ISM layers and a ferroelectric layer to amplify the tunneling barriers in the device. The ISM layers may form material dipoles that add to the effect of ferroelectric dipoles in the ferroelectric material.

### TECHNICAL FIELD

This disclosure describes ferroelectric devices that include interface switching modulation (ISM) layers that enhance the operation of the devices. Specifically, ferroelectric transistors and tunnel junction devices include ISM layers such that material dipoles reinforce internal electric fields.

### BACKGROUND

Many different types of transistors may be used to implement the basic components of neural networks and other modern systems. However, a specific family of devices known as ferroelectric devices have not been put into widespread use. A ferroelectric device is a logic/memory device that can maintain its logical/memory state even when power is removed. Ferroelectric devices may be similar to traditional metal oxide silicon (MOS) devices, except that the some of the dielectric material may be replaced with a ferroelectric material. The ferroelectric material may act like a dielectric that “remembers” or stores electric fields to which it has been exposed. In a ferroelectric device, a persistent dipole (or so-called “domain”) may be formed within the gate dielectric itself, thereby splitting the threshold voltage of the FeFET into stable states that can represent logic states. Because these stable states are persistent, the operation of a device may store state information as is done in a traditional charge-based Flash memory cell. Ferroelectric devices may also use a relatively small amount of power and may be scalable alongside traditional CMOS technologies. The read/write time is faster and the write/erase voltage is lower for ferroelectric devices than for traditional memories such as Flash NAND memory.

### BRIEF SUMMARY

In some embodiments, a ferroelectric field-effect transistor that is enhanced by interface switching modulation may include a gate electrode, a silicon channel between a source and a drain of the transistor, a ferroelectric layer located between the gate electrode and the silicon channel; and one or more interface switching modulation (ISM) layers located between the gate electrode and the silicon channel. Each of the one or more ISM layers may include a layer of hafnium oxide, a layer of silicon oxide, and a monolayer of titanium oxide between the layer of hafnium oxide and the layer of silicon oxide.

In any embodiments, any or all of the following features may be implemented in any combination and without limitation. The one or more ISM layers may be located between the gate electrode and the ferroelectric layer. The transistor may include second one or more ISM layers located between the ferroelectric layer and the silicon channel. The layer of hafnium oxide and the layer of silicon oxide in each of the one or more ISM layers may be approximately 2 nm thick. A work function of the gate electrode and a doping of the silicon channel may be designed to generate a predefined on-voltage in the transistor. The transistor may be one of a plurality of transistors forming connections in a neural network, where the transistor may include connections with other neural network nodes. The ferroelectric layer may include a plurality of ferroelectric dipoles with polarities that are controlled by a gate voltage, and each of the one or more ISM layers may include material dipoles with polarities that are controlled by the gate voltage.

In some embodiments, a ferroelectric tunnel junction device that is enhanced by interface switching modulation may include a first electrode, a second electrode, a ferroelectric layer located between the first electrode and the second electrode, and one or more interface switching modulation (ISM) layers located between the first electrode and the second electrode. Each of the one or more ISM layers may include a layer of hafnium oxide, a layer of silicon oxide, and a monolayer of titanium oxide between the layer of hafnium oxide and the layer of silicon oxide.

In any embodiments, any or all of the following features may be implemented in any combination and without limitation. The ferroelectric layer may be approximately 10 nm thick. The ferroelectric layer may be located between the first electrode and the one or more ISM layers. The one or more ISM layers may be located between the ferroelectric layer and the second electrode. The one or more ISM layers may include a plurality of ISM layers. The one or more ISM layers include three ISM layers. The device may also include connections to a neural network. The ferroelectric layer may include a plurality of ferroelectric dipoles with polarities that are controlled by a voltage applied across the first electrode and the second electrode, and each of the one or more ISM layers may include material dipoles with polarities that are controlled by the voltage applied across the first electrode and the second electrode.

In some embodiments, a method of fabricating a ferroelectric device that is enhanced by interface switching modulation may include depositing a first electrode, depositing a second electrode, depositing a ferroelectric layer located between the first electrode and the second electrode, and depositing one or more interface switching modulation (ISM) layers located between the first electrode and the second electrode. Each of the one or more ISM layers may include a layer of hafnium oxide, a layer of silicon oxide, and a monolayer of titanium oxide between the layer of hafnium oxide and the layer of silicon oxide.

In any embodiments, any or all of the following features may be implemented in any combination and without limitation. The first electrode may include a gate electrode of a ferroelectric transistor. The first electrode may include an electrode of a ferroelectric tunnel-junction device. The monolayer of titanium oxide may be deposited using a deposition process such that the monolayer of titanium oxide may include titanium ions that have not formed a crystal lattice. The layer of hafnium oxide and the layer of silicon oxide may generate oxygen ions in the one or more ISM layers, and the layer of titanium oxide may generate titanium ions in the one or more ISM layers, such that the oxygen ions and the titanium ions may form material dipoles in response to an applied voltage.

### BRIEF DESCRIPTION OF THE DRAWINGS

A further understanding of the nature and advantages of various embodiments may be realized by reference to the remaining portions of the specification and the drawings, wherein like reference numerals are used throughout the several drawings to refer to similar components. In some instances, a sub-label is associated with a reference numeral to denote one of multiple similar components. When reference is made to a reference numeral without specification to an

FIG. 1 illustrates how multiple memory states that may be realized in a single memory cell, according to some embodiments.

FIG. 2 illustrates a switching cycle for a ferroelectric device, according to some embodiments.

FIG. 3 illustrates a graph of the effects of the different mechanisms that determine the memory window in a ferroelectric memory, according to some embodiments.

FIG. 4A illustrates an ISM-enhanced device in an erased condition, according some embodiments.

FIG. 4B illustrates the ISM device in a programmed condition, according some embodiments.

FIG. 5 illustrates how a plurality of layers may be stacked on top of each other to multiply the effect of the electric field, according some embodiments.

FIG. 6 illustrates a hysteresis diagram of enhanced ferroelectric devices with varying numbers of ISM layers, according to some embodiments.

FIG. 7 illustrates an energy band diagram for a set of ISM layers, according to some embodiments.

FIG. 8A illustrates an ISM e-FeFET implementation, according to some embodiments.

FIG. 8B illustrates the ISM e-FeFET implementation when being programmed to a non-0 state, according to some embodiments.

FIG. 9 illustrates an ISM e-FTJ implementation, according to some embodiments.

FIG. 10A illustrates how an ISM e-FTJ device affects the tunneling barrier in comparison to regular FTJ devices, according to some embodiments.

FIG. 10B illustrates how the ISM e-FTJ device affects the tunneling barrier when a voltage is applied in the opposite direction, according to some embodiments.

FIG. 11 illustrates how a plurality of ISM e-FTJ devices and/or a plurality of ISM e-FeFET devices may be fabricated as vertical devices, according to some embodiments.

FIG. 12 illustrates a flowchart of a method for fabricating a ferroelectric device that is enhanced by interface switching modulation, according to some embodiments.

### DETAILED DESCRIPTION

Solid-state drives (SSDs) repressing the majority of modern memory devices and may rely on Flash memory technology for their implementations. For example, SSDs may use three-dimensional (3-D) charge-trapping and floating gate NAND technologies. Flash was chosen because of its reliability and its ability to store multiple memory states instead of classical binary 0 and binary 1 states found in 1-bit memories. Multiple memory states has been enabled by the very wide memory window of Flash memory which enables multiple memory states to be “squeezed” into the memory window beyond the traditional binary 0 and 1 states of the 1-bit solutions. Memory technologies that can represent multiple bits of information in a single memory cell are becoming more important in emerging technologies, as they not only increase the storage density, but also reduce the fabrication cost per bit of the memory.

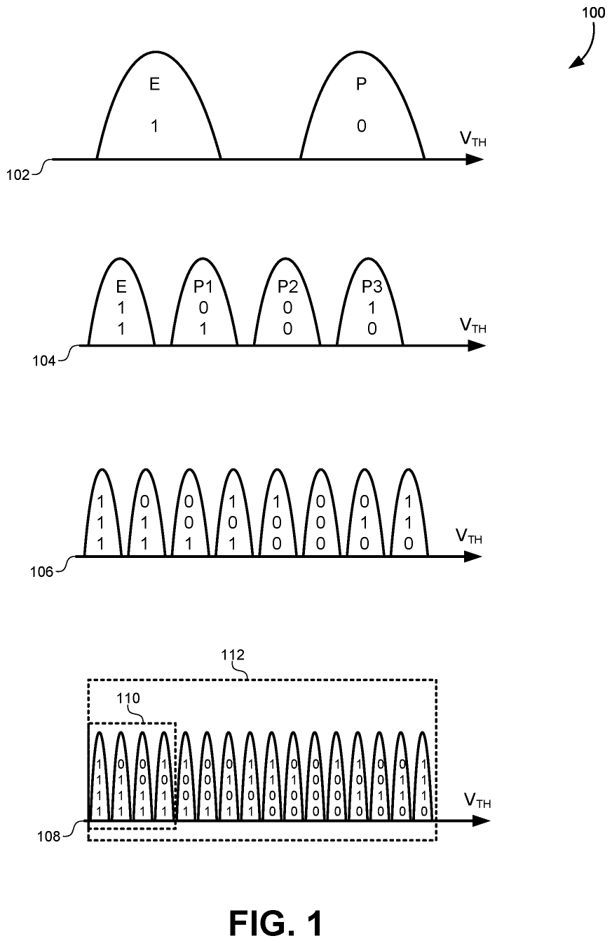

FIG. 1 illustrates how multiple memory states that may be realized in a single memory cell, according to some embodiments. FIG. 1 illustrates variability distributions of threshold voltage of the memory states in different cell realizations. First, a Single Level Cell (SLC) 102 may include two states, one corresponding to an “erase” for binary 1, and one corresponding to a “program” for binary 0. The SLC 102 represents a traditional memory structure that can be set to one of two states, thus representing one bit of information per cell. A Multi-Level Cell (MLC) 104 may include up to four states, one corresponding to an erase state with binary 11, and three program states corresponding to binary 01, 00, and 10. A Triple Level Cell (TLC) 106 memory may include up to eight states, one corresponding to an erase state with binary 111, and seven intermediate program states corresponding to binary 011, 001, 101, 100, 000, 010, and 110. Similarly, a Quad Level Cell (QLC) may include up to 16 states, with one erase state and 15 program states to store four bits of information per cell. In Flash memory cells, those states (or the positions of the threshold voltages) are proportional to the amount of charge trapped within the device.

Despite the advantages of using Flash memory described above, certain technical problems still exist as modern use cases shift to lower-power and faster designs with higher array periphery area-efficiency requirements. Flash memory requires a relatively high voltage of approximately 25 V to program a single bit in the memory cell. Additionally, Flash memory uses relatively long voltage pulses during a programming operation. These pulses may last between 100 μs and a few milliseconds. While these voltage ranges and pulse lengths may be acceptable for long-term storage devices, they are acceptable for many modern memory applications that require fast, low-power memories. Additionally, additionally circuitry is usually required to provide 25 V signals for the program and erase voltages. For example, charge pumps are required to increase the biasing voltage level up to 25 V. These charge pumps consume area in the cell and result in a lower die utilization as the ratio of memory array to periphery circuits drops. This in turn increases the cost per bit to manufacture the memory array.

To solve the technical problems associated with the speed and voltage requirements presented by Flash memories, the embodiments described herein may use ferroelectric memory elements to implement relatively low-power, high-speed memory devices. The ferroelectric memory elements described herein may use as little as 2 V-4 V when programming individual bits, and the programming pulse lengths may be on the order of approximately 10 ns. Because the ferroelectric dipoles can switch so rapidly and readily using these fast low-voltage pulses, ferroelectric memory elements may be better suited for low-power, high-speed memory applications, such as neural networks and in-memory computing.

One existing problem that has previously prevented the widespread use of ferroelectric materials involves the width of the “memory window” that allows for multiple bit states to be saved in a single memory element. In case of the one-transistor, one-capacitor (1T-1C) realization of ferroelectric memory (i.e. an FRAM), the memory window may refer to a width of a hysteresis loop in the applied polarization/voltage curves associated with a memory element. The higher the polarization, the greater the ability to store additional polarization states that can be discreetly represented in the memory without significant overlap. In contrast to the 1T-1C realization, a single-transistor (1T) ferroelectric memory provides a memory window proportional to the thickness of ferroelectric material and the coercive field. The coercive field refers to the internal barrier that needs to be overcome to flip the state of the memory from one state to other (e.g. from a programmed state to an erased state). In a partial switching implementation, the memory window of a ferroelectric field effect transistor (FeFET) is proportional to the number of domains that are switched, which in turn alters the transistor's channel conductivity. For example, multiple voltage thresholds or multiple current states may be realized within a large memory window by applying pulses with either different voltage amplitudes or different pulse length s to the device. These applied voltages may result in intermediate states (i.e., partial switching of the dipoles) in the ferroelectric material. When the state of the ferroelectric device is read, the intermediate state may cause an intermediate voltage or current output that can be decoded as an intermediate state between a fully programmed and a fully erased state.

In FIG. 1, a memory window 112 associated with a Flash memory is shown to be relatively large such that it may accommodate 16 discrete, non-overlapping states storing 4 bits of information in a single memory element. In contrast, a memory window 110 for a standard ferroelectric memory is illustrated in comparison to the memory window 112 of the Flash memory. Because of the smaller width of the memory window 110 for the ferroelectric memory, it is very difficult to realize multiple memory states in configurations such as QLC 108 or TLC 110 using existing ferroelectric techniques.

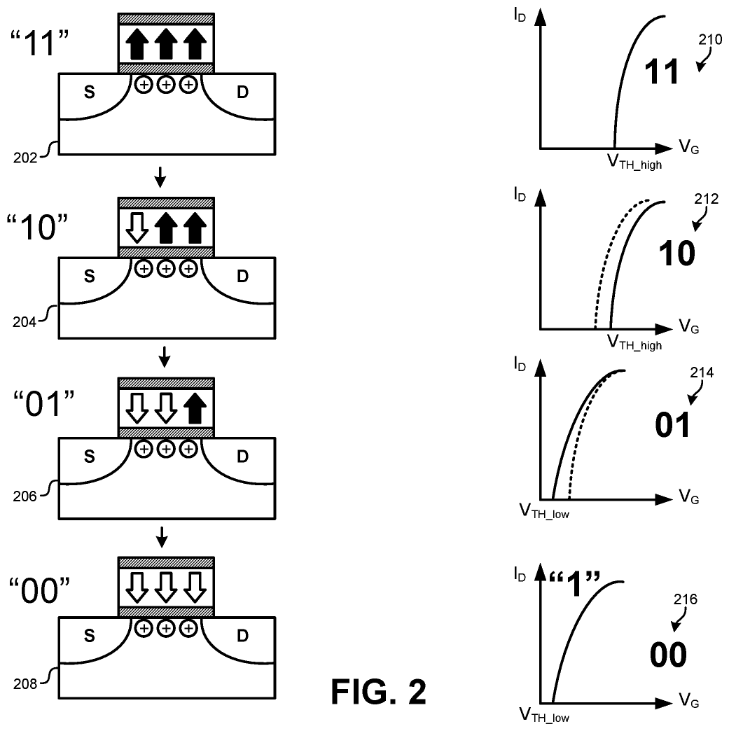

FIG. 2 illustrates a switching cycle for a multi-level ferroelectric device, according to some embodiments. This example illustrates a 1T FeFET implementation. Ferroelectric materials are materials that may change their state upon application of an external excitation, such as an applied voltage. Ferroelectric materials may include a plurality of physical domains that may individually be toggled between two stable states. Ferroelectric materials may be integrated to form, for example, a gate of a ferroelectric transistor (FeFET), which may be used as a memory device. Each of the FeFET states 202, 204, 206, 208 on the left-hand side of FIG. 2 may represent various states for a FeFET as it gradually transitions between a logic 00 and a logic 11 state. Specifically, these states represents different polarization orientations with resultant changes conductivity.

In this example, a negative voltage may be applied to the top of the gate in state 202. This negative voltage may cause dipoles in the ferroelectric material to be oriented with a positive polarity on top towards the top of the gate and a negative polarity on the bottom towards the silicon channel. This induces a positive charge accumulation (e.g., holes) in the p-type semiconductor, which is a Si channel in this example. This may be described as a reset or erase operation. In order to overcome the positive charge in the channel, a relatively high voltage may be applied to the gate to read the value of the memory element as illustrated in graph 210. When increasingly negative voltage pulses are applied to the gate of the device, the dipoles in the ferroelectric material may begin to switch and gradually transition the direction of those dipoles such that the negative polarity is oriented towards the top of the gate and the positive polarity is oriented towards the silicon channel. This induces an increasingly negative polarity in the channel by attracting minority carriers, which in a p-type Si-channel are electrons. This transition may be gradual, switching a few regions at a time in the ferroelectric material to progress through states 204, 206, and 208. As illustrated in graphs 212, 214, and 216, the voltage required to read the memory device as the ferroelectric material switches gradually becomes lower. This difference between V_{TH_high} and V_{TH_low} may represent the memory window of the device for a single bit cell where all 4 threshold states can implement a 2-bit memory device or 2-bit “digital” synapse.

For example, to model synaptic, analog behavior, a FeFET may be designed to have a comparatively larger area than the similar abovementioned “digital” synaptic devices, such that the gate electrode can be represented as a large plurality of domains, or physical regions that can independently switch in the gate electrode between logic states. Each of these domains is represented in FIG. 2 using the vertical arrows on the gate electrodes of the FeFET in various states 202, 204, 206, 208. The direction of these vertical arrows changes direction to represent the switching behavior of a corresponding domain in the gate. Changing one of the domains in the FeFET may correspond to a change in the structure of the ferroelectric crystal lattice material or a nucleation of the domain in the FeFET. Because the crystal lattice itself changes its configuration or the domain nucleates partially, the state of the FeFET can persist between the input pulses that cause the domains to switch or nucleate. Furthermore, each domain may be represented with its own hysteresis diagram that switches between stable states. Thus, when a single pulse is received at the gate of the FeFET, one of the domains may switch between stable states, such as transitioning from a fully erased state to a fully programmed state (e.g., binary 00 to 01, 10 to 11, etc.). Note that any implementation using a FeFET as a synapse or neuron in a neural network is only one example of the many different applications for which a ferroelectric memory may be used, and it is not meant to be limiting.

Beginning with the FeFET state 202 at the top of FIG. 2, the FeFET may begin in a logic 00. In this example, the FeFET may be designed to include three distinct domains, although in practice devices may include fewer or many more domains than three. Each of the three vertical arrows pointing up indicates that each of the three domains is currently in the stable logic 00 state. After receiving a first input pulse of opposing polarity compared to one required to reside in logical 0 state, the FeFET may enter state 204 (i.e., 01). In state 204, the first domain of the FeFET has switched from a logic 00 to a logic 01. This also is indicated in graph 212. The received input pulse was sufficient to change a single domain, while leaving the other domains at previous state. All combined domains at this stage may now represent the state 01. Note that some transitions may require multiple pulses to switch a single domain. Next, a second input pulse may be received by the FeFET, causing a second domain of the FeFET to transition to the opposing polarization state, which combined with the other domains define a logic 10 state. This is represented by the second arrow in the gate of the FeFET changing to point downwards in the illustration of state 206. Finally, a third input pulse may be received by the FeFET, causing the final domain to transition to the opposing polarization state, which together with the other domains define the logic 11 state.

This gradual transition of domains within the FeFET with a plurality of domains may provide the analog-like transition between states that is useful in modeling synaptic behavior. Before receiving any input pulses, state 202 represents a full logic 00 state for the FeFET. Conversely, after receiving a sufficient number of input pulses (e.g., at least three pulses), state 208 represents a full logic 11 state for the FeFET. As each of the domains switch independently, the conductivity of the channel in the FeFET may gradually change between a nonconductive state and a fully conductive state in a corresponding manner. This change in conductivity may cause the output of the synapse to also gradually increase/decrease as positive/negative input pulses are received to switch the corresponding domains.

In addition to representing neurons and synapses in an artificial neural network, the FeFET illustrated in FIG. 2 may also represent a multi-state memory device. A predefined number of voltage pulses or a predefined voltage level may be applied to the gate of the FeFET to cause a known number of domains to switch. As described above, domains switching individually may represent different memory states that are persistently stored by the device. Different levels of conductivity through the channel of the FeFET may be read to determine the state of the device, and may thereafter be translated into a bit state.

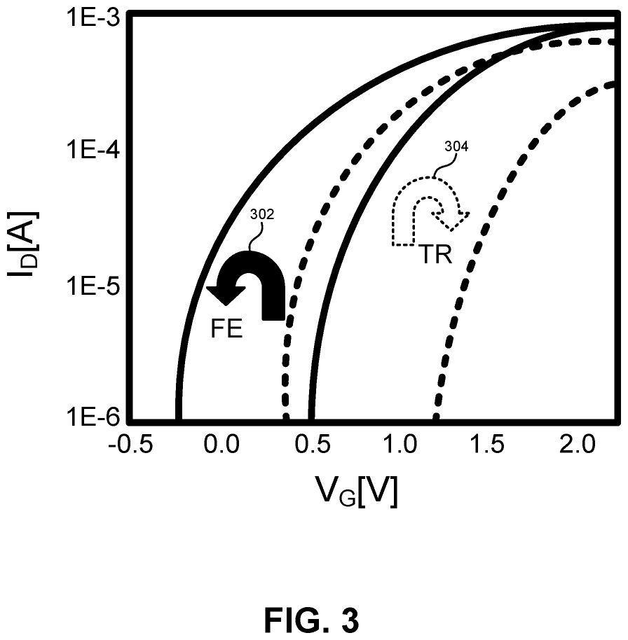

FIG. 3 illustrates a graph of the effects of the different mechanisms that determine the memory window in a ferroelectric memory, according to some embodiments. As described above, the switching of ferroelectric dipoles in the ferroelectric material may move the hysteresis curve. The graph in FIG. 3 illustrates a portion of this hysteresis curve. As a voltage is applied and dipoles begin to flip in a programming operation, the state of the device will move around the hysteresis curve in a counterclockwise direction 302.

In addition to the ferroelectric dipoles, the ferroelectric device may also be affected by trapped charges within the device. Referred to as “charge trapping,” electrons trapped within the device's dielectric cause a shift of the threshold voltage of device toward more positive gate voltages. However, instead of traveling in a counterclockwise direction 302, the effect of the charge trapping may traverse the hysteresis curve in a clockwise direction.

One of the reasons for the smaller memory window in ferroelectric devices is the effect of parasitic charge trapping. Specifically, parasitic charge trapping may counteract the effect of the dipole created by the ferroelectric switching. Because these two effects tend to counteract each other, exerting influence in opposite directions, the width of the memory window in ferroelectric devices may be substantially reduced. Because charge trapping may result in a clockwise effect while ferroelectric switching may result in a counterclockwise effect, the memory window generated by the ferroelectric effect may be reduced. Added together, the net result is a counterclockwise effect due to ferroelectric switching that has a smaller hysteresis or threshold voltage shift and a cumulatively smaller ferroelectric memory window.

Some of the embodiments described herein may use a ferroelectric device combined with additional layers that provide interface switching modulation (ISM) effect to overcome these challenges by overcompensating for the parasitic charge trapping and creating a memory window in a hybrid ferroelectric device that is large enough to represent more than four states and enable the reliable operation of a memory device with more than a 2-bit capacity. The ISM layers that may be added to a ferroelectric device may create material dipoles that react to applied voltages in much the same way that ferroelectric dipoles react to applied voltages. However, the material dipoles in the ISM layers tend to interact constructively with the effect of the ferroelectric dipoles. Both the ferroelectric dipoles in the material dipoles have an effect that moves around the threshold voltage of device in a counterclockwise direction. Therefore, instead of the countering effect of the ferroelectric dipoles like the charge trapping phenomena described above, these embodiments instead increase the size of the memory window by additively combining the effects of the ferroelectric dipoles and the material dipoles.

In addition to additively increasing the memory window, the ISM material dipole described below is reversible, such that they may be both reset and set to represent binary 0 and binary 1 levels. The ISM materials may also follow the reversibility and reorientation of the ferroelectric dipole. The resulting dipoles caused by both the ferroelectric material and the ISM layers may generate individual internal electric fields oriented in the same direction. The individual electric fields may combine their effective strength additively to form an overall internal electric field within the active layers (ferroelectric and ISM) of the device. This overall internal electric field may be used for the development of enhanced ferroelectric tunnel junction devices (ISM e-FTJs) where the ISM layers are used as an enhancer of the polarization in the ferroelectric tunnel junction. These materials may also be used to form enhanced ferroelectric field effect transistors (ISM e-FeFETs) where the ISM layers enhance the internal field generated by polarization of the ferroelectric material within the FeFET.

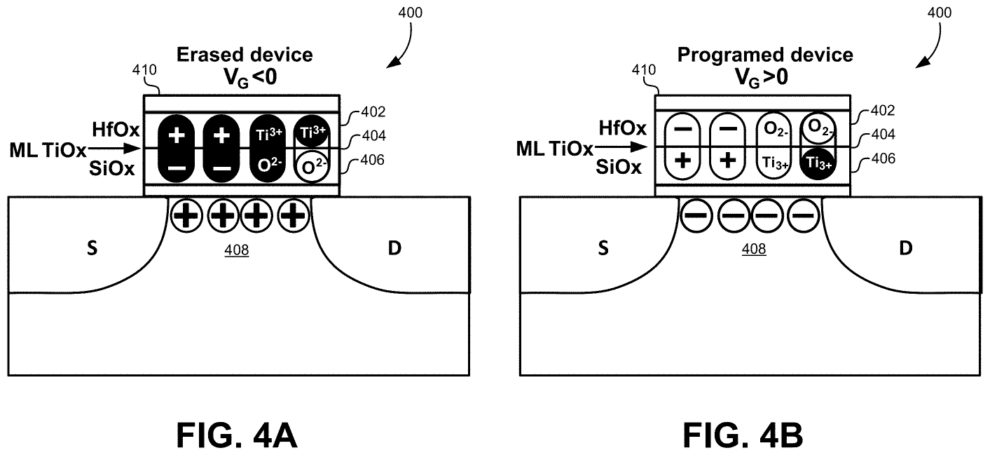

FIG. 4A illustrates an transistor-based, ISM-enhanced device in an erased condition, according some embodiments. In comparison to the device of FIG. 2, this device 400 may use a number of ISM layers in the gate of a transistor. This example may use a layer of hafnium oxide 402, a monolayer of titanium oxide 404, and a layer of silicon oxide 406. The layer of titanium oxide 404 may be described as a monolayer, or a layer that is not completely formed into a crystal lattice, but rather exists primarily as ions mixed between the hafnium oxide 402 and silicon oxide 406. The monolayer of titanium oxide 404 may be grown using an ALD process, a CVD process, or PVD sputtered on in a very thin, precise layer.

The hafnium oxide 402 may have a strong affinity for oxygen ions. Therefore, the hafnium oxide may remove oxygen ions from the silicon oxide 406 such that the silicon oxide 406 becomes depleted. The result is an excess of oxygen ions in the ISM layers. Additionally, because the titanium oxide exists as a monolayer as ions, an excess of titanium ions may also roam freely in this area around the other materials. Therefore, the resulting material in the gate device has available titanium ions and oxygen ions.

When a negative voltage is applied to the gate 410, the positive titanium ions will be attracted to the top of the gate 410, while the negative oxygen ions will be repelled towards the bottom of the gate towards the channel 408. This effectively creates a dipole using the positive titanium ions and the negative oxygen ions. This dipole forms an electric field in the device and in turn changes the conductivity of the channel 408 to a positive polarity by attracting majority carriers and setting the device into an accumulation mode in the case of p-type semiconductors. In consequence, a threshold voltage shift toward higher gate voltages or a higher voltage may be need to be applied to a gate of the device to turn on the transistor.

FIG. 4B illustrates the ISM device in a programmed condition, according some embodiments. In contrast to the operation explained above in FIG. 4A, this example may apply a positive voltage to the gate 410 in order to program the device 400. The negative oxygen ions may be attracted to the top of the gate 410, while the positive titanium ions may be repelled towards the bottom of the gate 410 towards the channel 408. This effectively flips the polarity of the material dipoles formed by the titanium and oxygen ions. This generates an internal electric field in the opposite direction such that negative minority carriers (in case of p-type semiconductors) are attracted and the channel 408 is inverted. As a consequence, a threshold voltage shift toward lower gate voltages may be applied to a gate to turn on the transistor.

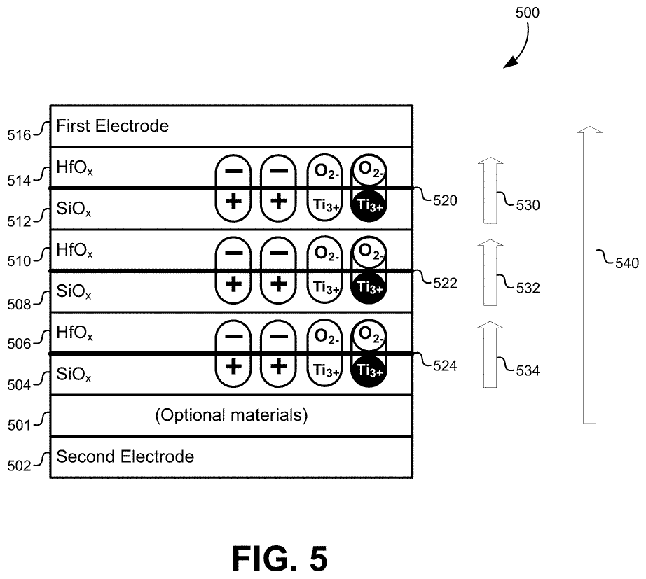

FIG. 5 illustrates how a plurality of layers may be stacked on top of each other to multiply the effect of the internal electric field resulting from material dipole generation, according some embodiments. Instead of a single hafnium oxide and silicon oxide layer pair separated by a monolayer of titanium oxide, the example of FIG. 5 stacks a plurality of these layer combinations on top of each other within the device. The device may include a first electrode 516 manufactured using any conductive metal material. After the first electrode 516, a hafnium oxide layer 514, a titanium oxide monolayer 520, and a silicon oxide layer 512 may be assembled as described above in FIG. 4A. Beneath these layers, any number of additional hafnium/titanium/silicon layer combinations may be added. In this example, the device may include a second hafnium oxide layer 510, a second titanium oxide monolayer 522 and a second silicon oxide layer 508. The device made further include a third hafnium oxide layer 506, a third titanium oxide monolayer 524, and a third silicon oxide layer 504. This example then includes a second electrode 502 manufactured from any conductive metal. In some embodiments, optional materials 501 may also be included such as a semiconductor layer in case of a transistor realization as illustrated above. Note that optional additional materials may also be included between any or all of the other layers depicted in FIG. 5. Alternatively, some embodiments may include no additional layers not explicitly illustrated in FIG. 5.

Each of the individual layer combinations illustrated in FIG. 5 may generate oxygen and titanium material dipoles within those layers as described above. For example, dipoles may be formed in layers 514, 520, and 512. Dipoles may also be formed in layers 510, 522, and 508, as well as layers 506, 524, and 504 as illustrated in FIG. 5. Each of these material dipoles may form within the layer combinations and thus may form a corresponding internal electric field. For example, the dipoles formed in layers 514, 520, and 512 may form an internal electric field 530. The material dipoles formed in layers 510, 522, and 508 may form an internal electric field 532. The material dipoles formed in layers 506, 524, and 504 may form an internal electric field 534. Each of the internal electric fields 530, 532, 534 may be formed in the same direction such that an overall internal electric field 540 may be formed in the device. Thus, the addition of more layer combinations may have an additive effect on the strength of the electric field 540.

As the strength of the internal electric field 540 increases, its impact on inversion and accumulation of channel, and its effect on the memory window for the device may also increase. Not only is the electric field 540 strengthened, but the effect of the reversal of this internal electric field 540 during program/erase cycles is counterclockwise in the drain-current/gate voltage hysteresis diagram, which aligns with the counterclockwise effect of the ferroelectric dipoles described above.

Each combination of a hafnium oxide layer, a titanium oxide monolayer, and a silicon oxide layer may be referred to herein as an ISM layer. For example, layers 504, 520, and 512 may form a first ISM layer; layers 510, 522, and 508 may form a second ISM layer; and layers 506, 524, and 504 may form a third ISM layer. Throughout this disclosure, any instance of a single ISM layer may be replaced with multiple ISM layers. Single ISM layers are illustrated in most of the figures for the sake of clarity. However, in any embodiment and in any of the examples described herein, a single ISM layer may represent one or more ISM layers stacked on top of each other without limitation.

In additional to multiple ISM layers being present within the device 500 that are not specifically illustrated in FIG. 5, additional layers of other materials may also be present. For example, an additional layers may be placed between the first electrode 516 and the first hafnium oxide layer 514. Additional layers may also be placed between the first silicon dioxide layer 512 and the second hafnium oxide layer 510. For example, additional ferroelectric layers may be placed below the first electrode 516 and/or on top of the second electrode 502 as described in in the ISM e-FeFET and ISM e-FTJ embodiments described in detail below.

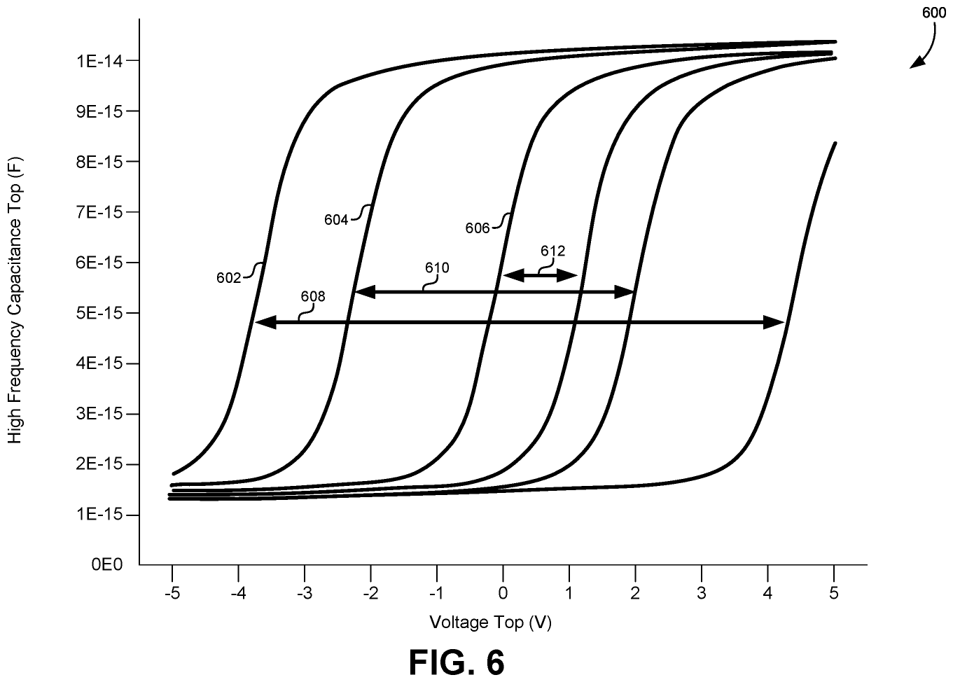

FIG. 6 illustrates a hysteresis diagram of enhanced ferroelectric devices with varying numbers of ISM layers, according to some embodiments. Note that the capacitance values on the Y-axis are specific to one particular implementation. These values are not meant to be limiting, and it will be understood that different implementations may exhibit very different capacitance values. These values are provided only by way of example. The capacitance-voltage hysteresis curve 606 for a metal-ISM-semiconductor (MISMS) device at the center of the diagram 600 corresponds to a device with only a single ISM layer comprising a combination of hafnium/titanium/silicon-based layers as described above. Note that the memory window 612—which is the difference between two flatband voltages—is less than approximately 2 V. However, as a second ISM layer is added to the device, the hysteresis curve 604 is generated. This hysteresis curve 604 yields a memory window 610 of more than approximately 4 V. Finally, adding a third ISM layer generates hysteresis curve 602, which yields a memory window 608 of more than approximately 8 V. In this implementation, the number of layers is shown to be directly proportionality to the internal electric field generation, which in turns results in flatband voltage shifts that open the memory window to be large enough to accommodate additional states. This large memory window exists all within the voltage range of approximately −5 V to approximately +5 V. Thus, the ISM layers used in the embodiments described herein may generate a large memory window while still maintaining a relatively low operating voltage level.

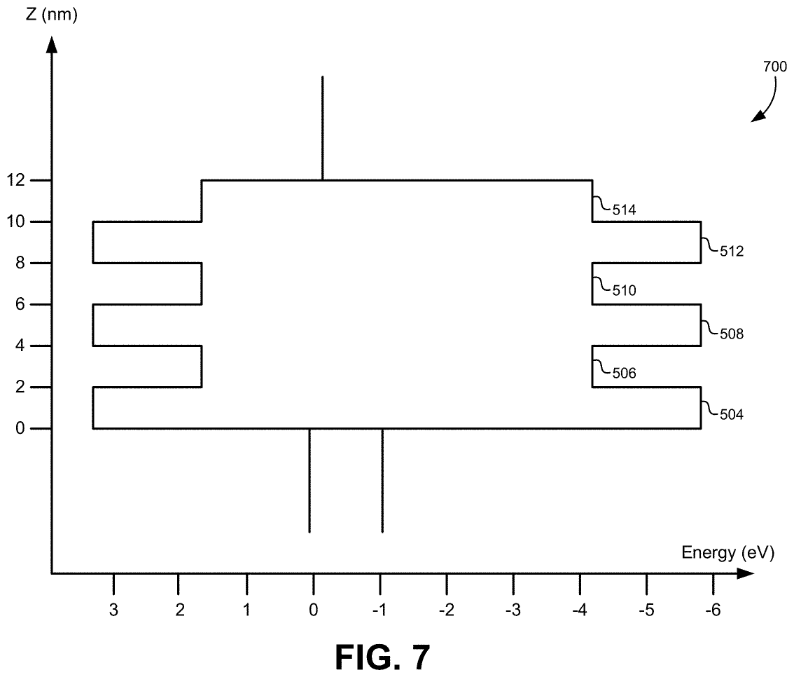

FIG. 7 illustrates an energy band diagram 700 for a set of ISM layers, according to some embodiments. The layers may include hafnium-based layers 514, 510, 506 as illustrated above in FIG. 5. The layers may also include silicon-based layers 512, 508, 504. Each pair of hafnium/silicon layers may include a monolayer of titanium oxide. However, these monolayers are not illustrated in FIG. 7 because their thickness may be negligible compared to the hafnium-based layers 514, 510, 506 and/or the silicon-based layers 512, 508, 504. The horizontal axis of the band diagram 700 represents the bandgap energy associated with each of the layers with respect to an electron attempting to move through those layers.

The vertical axis of the band diagram 700 illustrates the thickness of the various layers. In this embodiment, each of the layers is approximately 2 nm thick. Other embodiments may increase or decrease this thickness. For example, some embodiments may use silicon-based layers 512, 508, 504 that have a greater/lesser thickness than the hafnium-based layers 514, 510, 506, while other embodiments may be fabricated such that each of the silicon-based layers and hafnium-based layers are approximately the same thickness. The thickness of each layer may range from between approximately 1 nm and approximately 5 nm. Increasing the thickness of each of the layers beyond the 2 nm illustrated in FIG. 7 may increase the operating voltage of the device. Including multiple ISM layers of 2 nm thick layers of hafnium material and silicon material balances the increase in the operating voltage with the increase in the memory window.

Although hafnium oxide, silicon oxide, and titanium oxide are used as examples for materials in the ISM, other materials having similar properties may be used as substitutes. In any embodiments, the hafnium oxide may be replaced with materials such as ZrOx, HfOx, ZrOx doped with various elements such as Si, Al, Y, Sr, Gd, N, La, and/or any combination of these materials.

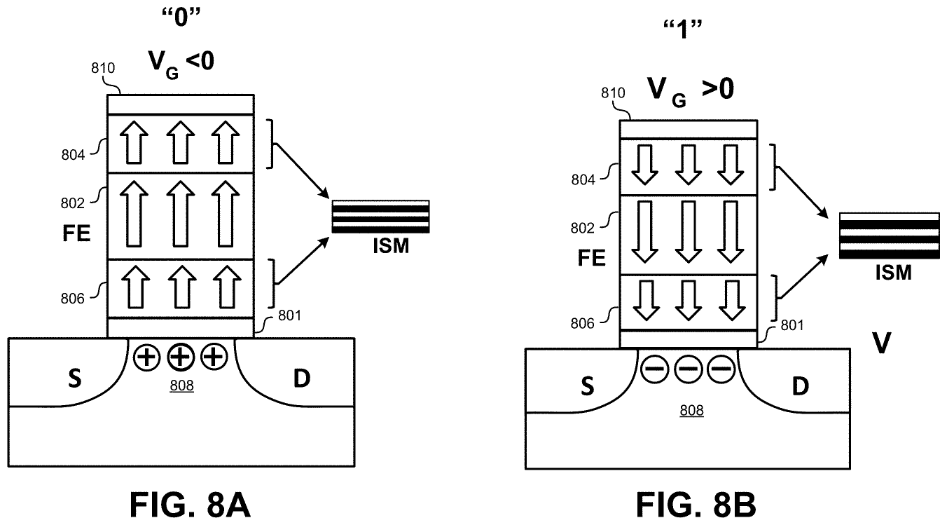

FIG. 8A illustrates an ISM e-FeFET implementation, according to some embodiments. This example may include a ferroelectric layer 802 beneath a gate 810 of the device. Additionally, the device may include one or more ISM layers 804, 806 that are fabricated beneath the gate 810 of the device. In this example, a first ISM layer 804 may be fabricated between the top electrode of the gate 810 and the ferroelectric layer 802. A second ISM layer 806 may be placed between the ferroelectric layer 802 and the channel 808. Each of the ISM layers 804, 806 may include pairs of hafnium-based material and silicon-based material with a monolayer of a titanium-based material between, or other similar materials may be used as listed above. For example, each of the ISM layers 804, 806 may include layers of hafnium oxide, titanium oxide, and silicon dioxide as described above in FIG. 5. In any embodiments, the ferroelectric layer 802 may be implemented using materials such as Sc:AlN, strained HfOx, HfOx, mixtures of HfOx and ZrOx (e.g., HZO, HfOx, and/or HZO doped with Si, Al, Y, Sr, Gd, N, La and other similar materials). Additionally, traditional ferroelectrics such as PZT, SBT, STO and BFO may be used instead of or in addition to transitional metal oxide ferroelectrics.

When a negative voltage is applied to the gate 810, ferroelectric dipoles may form in the ferroelectric layer 802 as described above in FIG. 2. Additionally, material dipoles may form in the ISM layers 804, 806 as described above in FIG. 5. Each of these dipoles may form and be oriented in the same direction such that the internally generated electric field generated by each of these dipoles is reinforced. This may cause the conductivity of the channel 880 to go into accumulation and represent a binary 0.

FIG. 8B illustrates the ISM e-FeFET implementation when being programmed to a non-0 state, according to some embodiments. As a positive voltage is applied to the gate 810, the ferroelectric dipoles in the ferroelectric layer 802 may reorient as described above in FIG. 2. Additionally, the material dipoles in the ISM layers 804, 806 may also reorient. The effect of this reversible dipole within the ISM layers 804, 806 is aggregated on top of the ferroelectric effect and magnifies the impact of the polarization on the conductivity of the channel 808. This results in an increase in the memory window of the device. The gate voltage can thus be used to control the polarities of the ferroelectric dipoles and the material dipoles in the device. This allows incremental voltage pulses to be applied to the gate 810 to gradually switch dipoles within both the ferroelectric layer 802 and the ISM layers 804, 806. Each of these domains switching in the ferroelectric layer 802 may correspond to a discrete memory state stored by the device. The ISM e-FeFET device may thus be used as a low-power, fast memory element that is able to persistently store more than two binary states in a single memory element.

The electrode on the gate 810 may be manufactured from any metal conductor, such as titanium, platinum, aluminum, and other similar materials. The electrode metal may be more than approximately 3 nm thick. The ferroelectric layer 802 may be between approximately 2 nm and approximately 20 nm thick. The size of the memory window is proportional to the thickness of the ferroelectric layer 802, so increasing the size of the ferroelectric layer 802 may increase the size of the memory window. However, increasing the thickness of the ferroelectric layer 802 may also increase the operating voltage proportionally. Therefore, a trade-off exists between increasing the size of the memory window and minimizing the operating voltage. Some embodiments have used a ferroelectric layer 802 having a thickness of approximately 10 nm as an acceptable balance between these two factors.

As with most FET transistor implementations, a silicon oxide interfacial barrier layer 801 may be placed above the channel and the gate stack constituents. The silicon oxide barrier 801 may be approximately 0.8 nm or less in thickness. Some embodiments may also control the doping of the silicon substrate and/or the halo implant for the device along with the work function of the metal material used for the electrode on the gate 810. Adjusting these two parameters can be used to tune the location of the voltage required to change the state of the device. For example, the differential between the doping of the substrate and the work functions of the metal used on the gate may be used to generate an internal electric field that adjusts the Vi level of the device. The circuit designer may specify a predefined on-voltage for the device and adjust the work function of the gate electrode and the doping of the silicon channel to generate the predefined on-voltage.

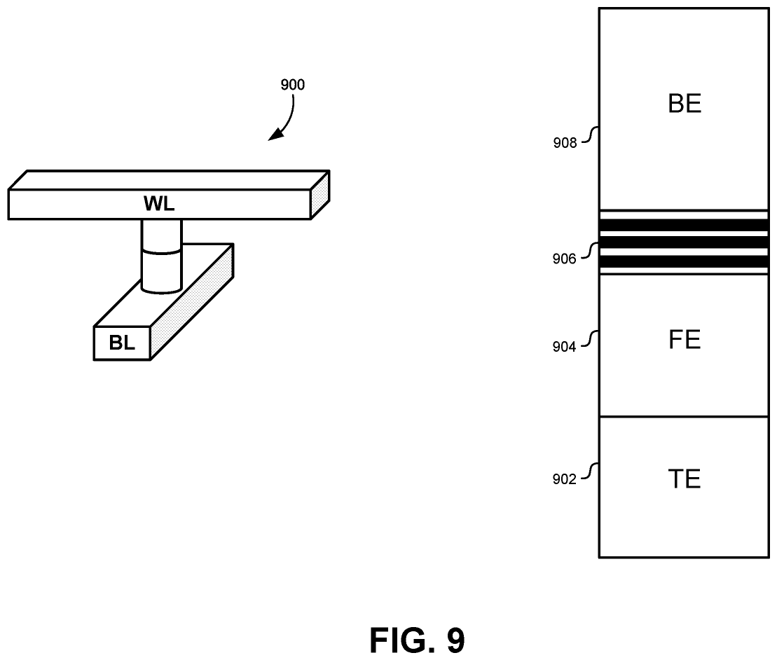

FIG. 9 illustrates an ISM e-FTJ implementation, according to some embodiments. In previous FTJ implementations, reversible ferroelectric dipoles modulate the tunneling barrier of the tunnel junction, resulting in the ON and OFF currents. The memory window of the FTJ is defined as a difference between the ON and OFF current at given read voltage. FTJ devices may be used extensively in neural networks to form a single neural node 900, which may use a selector and/or memory device for each neural connection. Therefore, each of the electrodes in the device may include connections to other neural network nodes. FTJ devices utilize the dipole formation within the ferroelectric material to modulate the band energy diagram to generate stable memory states.

To fabricate an ISM e-FTJ, one or more ISM layers may be added next to the ferroelectric layer of the device to further modulate the barrier and produce a tunneling improvement in the device. Just as the ISM layers amplified the effect of the ferroelectric dipoles to increase the memory window in the ISM e-FeFET, the material dipoles created by the ISM layer may amplify the band-bending effect produced by the ferroelectric dipoles in a two-terminal tunnel junction device and change the tunneling barrier and probability, which in turn enhances the memory window and distance between the ON and OFF currents.

An ISM e-FTJ may be fabricated by providing a top electrode 902 and a bottom electrode 908. These electrodes may also be referred to as first and second electrodes to distinguish them from each other. The top electrode 902 and the bottom electrode 908 may be fabricated using any conductive metal such as titanium, platinum, or other similar metals/alloys. In some embodiments, the top electrode 902 and/or the bottom electrode 908 may be fabricated using silicon, polysilicon, or highly doped Si or SiGe. In some embodiments, the materials used for the top electrode 902 and the bottom electrode 908 may be different. Each of these two materials may have different work functions, and the work function differential between these materials may generate an internal electric field that can be used to tune the current to turn on the device. The work function differential may also be used to tune retention tunneling for the device. For example, a work function differential may be created between the two electrodes 902, 908 of approximately 0.4 V-0.8 V to move the on-current to the desired level.

The device may also include a ferroelectric layer 904. The thickness of the ferroelectric layer 904 may be approximately 10 nm, and may be within the range of approximately 3 nm to approximately 20 nm. The ferroelectric layer 904 may be fabricated using a layer of hafnium oxide, a mixture of HfO₂ and ZrO₂, or other similar materials such as Sc:AlN, strained HfOx, HfOx, mixtures of HfOx and ZrOx, HZO, HfOx, or H₂O doped with Si, Al, Y, Sr, Gd, N, La and/or other similar materials. Additionally, traditional ferroelectrics such as PZT, SBT, STO and BFO may also be used instead of transitional metal oxide ferroelectrics. Next to the ferroelectric layer 904, one or more ISM layers 906 may be fabricated. For example, some embodiments may use one ISM layer, two ISM layers, three ISM layers, or more ISM layers to amplify the band-bending affect. One exemplary embodiment has used three ISM layers to produce effective results. The thickness of the internal hafnium oxide and/or silicon oxide layers in each of the ISM layers 906 may be approximately 1 nm to approximately 3 nm in thickness.

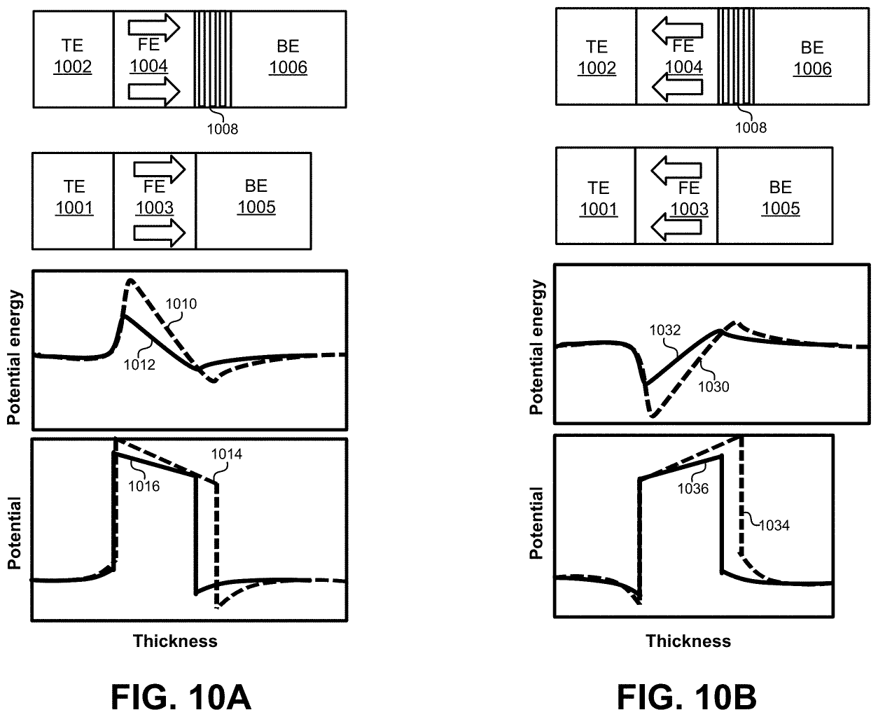

FIG. 10A illustrates how an ISM e-FTJ device affects the tunneling barrier in comparison to regular FTJ devices, according to some embodiments. A simple FTJ may include a top electrode 1001, a ferroelectric layer 1003, and a bottom electrode 1005. Curve 1012 and curve 1016 illustrate the tunneling barriers created by this device when a voltage is applied to the device to create an electric field from the top electrode 1001 to the bottom electrode 1005. Similarly, FIG. 10B illustrates how the ISM e-FTJ device affects the tunneling barrier when a voltage is applied in the opposite direction, according to some embodiments. Curve 1032 and curve 1038 illustrate the tunneling barriers created by this device when a voltage is applied in the opposite direction to create an electric field from the bottom electrode 1005 to the top electrode 1001. In both cases, the ISM layer amplifies the field generated by the ferroelectric dipoles and results in a steeper potential change and a higher modulation of the tunneling barrier, which in turn enhances the memory window.

FIG. 10A also shows an ISM e-FTJ device with a top electrode 1002 a ferroelectric layer 1004, one or more ISM layers 1008, and a bottom electrode 1006. The resulting curve 1010 and curve 1014 illustrate how the energy barriers are amplified by the one or more ISM layers 1008. This result may also be seen in FIG. 10B, where the resulting curve 1030 and curve 1034 illustrate how the energy barriers are amplified by the one or more ISM layers 1008 when polarized in the opposite direction. The additional field generated by superposition of the internal field of the ISM layer and internal field of ferroelectrics results in additional band bending, which makes the tunneling probability for the FTJ higher. This in turn opens the memory window of FTJ, thereby enabling additional states to be included in the memory window and enabling multi-level-cell operation.

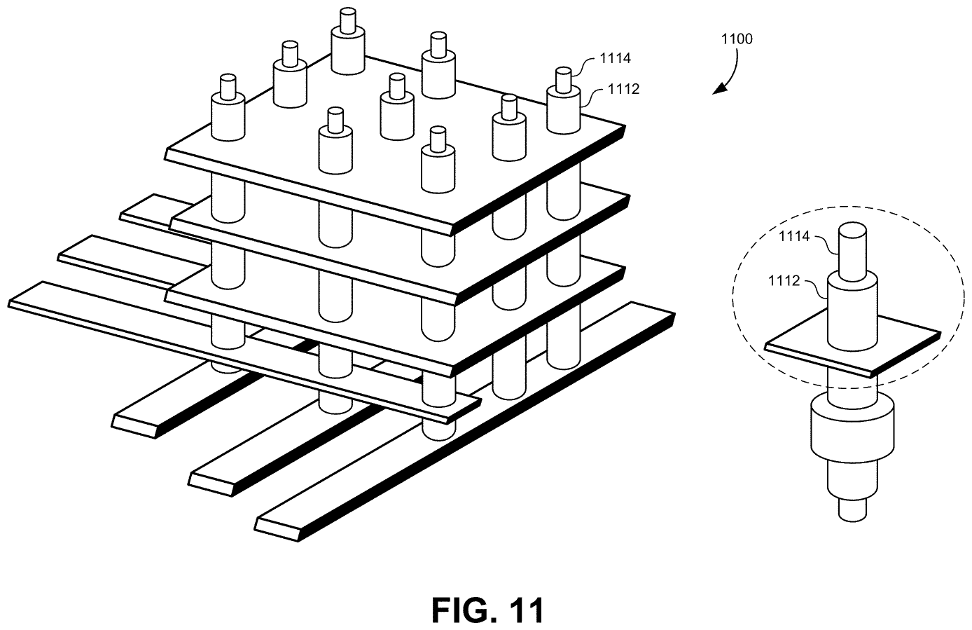

FIG. 11 illustrates how a plurality of ISM e-FTJ devices and/or a plurality of ISM e-FeFET devices may be fabricated as vertical devices, according to some embodiments. This fabrication process may be similar to how traditional NAND Flash devices are fabricated. For example, an ISM e-FeFET device may surround a vertical silicon channel 1114 with a ferroelectric layer and one or more ISM layers (collectively 1112) to form the gate of the transistor in a vertical array 1100. A similar process may be followed to fabricate a vertical array of ISM e-FTJ devices.

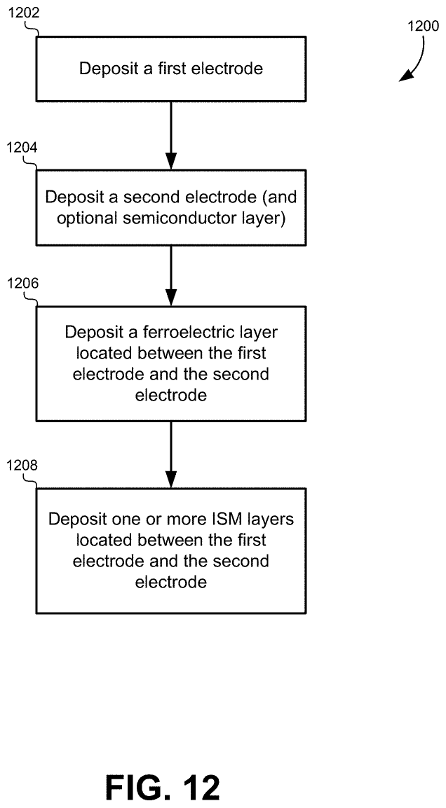

FIG. 12 illustrates a flowchart 1200 of a method for fabricating a ferroelectric device that is enhanced by interface switching modulation, according to some embodiments. The method may include depositing a first electrode (1202) and depositing a second electrode (1204). As described above, these electrodes may be fabricated from any metal or conductive alloy, along with materials such as doped silicon or SiGe semiconductors, and/or polycrystalline Si and LTPS. The electrodes may be fabricated from different materials such that a work function differential is created between the two electrodes. In some embodiments where an ISM e-FeFET is being fabricated, the first electrode may represent a gate electrode, and the second electrode may represent a semiconductor with source and drain regions defined through an implantation process with corresponding source and drain electrode terminals, respectively. In some embodiments where an ISM e-FTJ is being fabricated, the first electrode and the second electrode may represent opposite electrodes for the FTJ device. The method steps illustrated in flowchart 1200 do not imply an order in which the steps are carried out. Therefore, additional materials may be fabricated between the first electrode and the second electrode, including the ferroelectric layer and the one or more ISM layers described below. For example, some embodiments may deposit a semiconductor layer adjacent to the second electrode as used in the transistor devices described above.

The method may also include depositing a ferroelectric layer located between the first electrode and the second electrode/semiconductor (1204). The ferroelectric layer may be fabricated using any of the materials or techniques described above in this disclosure. The method may further include depositing one or more ISM layers also located between the first electrode and the second electrode/semiconductor. As described above, each of the ISM layers may be fabricated from three individual layers. For example, an ISM layer may include a layer of hafnium oxide, a monolayer of titanium oxide, and a layer of silicon oxide. Other similar materials may be substituted for these materials as described above.

The ferroelectric layer and the one or more ISM layers may be deposited in any order and in any combination. For example, an ISM e-FeFET process may deposit the first electrode as a gate electrode, a first number of ISM layers next to the gate electrode, a ferroelectric layer next to the first number of ISM layers, and a second number of ISM layers on the other side of the ferroelectric layer to form a transistor gate stack. A source and drain region may be defined in a semiconductor material to form a transistor device. In another example, an ISM e-FTJ process may deposit a first electrode, a ferroelectric layer next to the first electrode, one or more ISM layers next to the ferroelectric layer, followed by a second electrode. Other combinations, numbers, and distributions of ferroelectric layers and/or ISM layers may be deposited between the electrodes in any combination and without limitation. The specific configurations of ferroelectric layers and ISM layers illustrated in the figures are provided only by way of example and are not meant to be limiting.

It should be appreciated that the specific steps illustrated in FIG. 12 provide particular methods of fabricating a ferroelectric device that is enhanced by interface switching modulation according to various embodiments. Other sequences of steps may also be performed according to alternative embodiments. For example, alternative embodiments may perform the steps outlined above in a different order. Moreover, the individual steps illustrated in FIG. 12 may include multiple sub-steps that may be performed in various sequences as appropriate to the individual step. Furthermore, additional steps may be added or removed depending on the particular applications. Many variations, modifications, and alternatives also fall within the scope of this disclosure.

Throughout this disclosure, the term “approximately” may be used to describe values that occur within a range of −15% to +15% of the stated value. For example, a capacitance of approximately 100 nm may fall within the range of 85 nm to 115 nm.

In the foregoing description, for the purposes of explanation, numerous specific details were set forth in order to provide a thorough understanding of various embodiments. It will be apparent, however, to one skilled in the art that embodiments may be practiced without some of these specific details. In other instances, well-known structures and devices are shown in block diagram form.

The foregoing description provides exemplary embodiments only, and is not intended to limit the scope, applicability, or configuration of the disclosure. Rather, the foregoing description of the example embodiments will provide those skilled in the art with an enabling description for implementing an example embodiment. It should be understood that various changes may be made in the function and arrangement of elements without departing from the spirit and scope of various embodiments as set forth in the appended claims.

Specific details are given in the foregoing description to provide a thorough understanding of the embodiments. However, it will be understood by one of ordinary skill in the art that the embodiments may be practiced without these specific details. For example, circuits, systems, networks, processes, and other components may have been shown as components in block diagram form in order not to obscure the embodiments in unnecessary detail. In other instances, well-known circuits, processes, algorithms, structures, and techniques may have been shown without unnecessary detail in order to avoid obscuring the embodiments.

Also, it is noted that individual embodiments may have beeen described as a process which is depicted as a flowchart, a flow diagram, a data flow diagram, a structure diagram, or a block diagram. Although a flowchart may have described the operations as a sequential process, many of the operations can be performed in parallel or concurrently. In addition, the order of the operations may be re-arranged. A process is terminated when its operations are completed, but could have additional steps not included in a figure. A process may correspond to a method, a function, a procedure, a subroutine, a subprogram, etc. When a process corresponds to a function, its termination can correspond to a return of the function to the calling function or the main function.

In the foregoing specification, aspects various embodiments are described with reference to specific embodiments, but those skilled in the art will recognize that the invention is not limited thereto. Various features and aspects of the above-described embodiments may be used individually or jointly. Further, embodiments can be utilized in any number of environments and applications beyond those described herein without departing from the broader spirit and scope of the specification. The specification and drawings are, accordingly, to be regarded as illustrative rather than restrictive.

1. A ferroelectric field-effect transistor that is enhanced by interface switching modulation, the transistor comprising:
a gate electrode;
a silicon channel between a source and a drain of the transistor;
a ferroelectric layer located between the gate electrode and the silicon channel; and
one or more interface switching modulation (ISM) layers located between the gate electrode and the silicon channel, wherein each of the one or more ISM layers comprises:
a layer of hafnium oxide;
a layer of silicon oxide; and
a monolayer of titanium oxide between the layer of hafnium oxide and the layer of silicon oxide.

2. The transistor of claim 1, wherein the one or more ISM layers are located between the gate electrode and the ferroelectric layer.

3. The transistor of claim 2, further comprising second one or more ISM layers located between the ferroelectric layer and the silicon channel.

4. The transistor of claim 1, wherein the layer of hafnium oxide and the layer of silicon oxide in each of the one or more ISM layers is approximately 2 nm thick.

5. The transistor of claim 1, wherein a work function of the gate electrode and a doping of the silicon channel are designed to generate a predefined on-voltage in the transistor.

6. The transistor of claim 1, wherein the transistor is one of a plurality of transistors forming connections in a neural network, wherein the transistor comprises connections with other neural network nodes.

7. The transistor of claim 1, wherein the ferroelectric layer comprises a plurality of ferroelectric dipoles with polarities that are controlled by a gate voltage, and wherein each of the one or more ISM layers comprises material dipoles with polarities that are controlled by the gate voltage.

8. A ferroelectric tunnel junction device that is enhanced by interface switching modulation, the device comprising:
a first electrode;
a second electrode;
a ferroelectric layer located between the first electrode and the second electrode; and
one or more interface switching modulation (ISM) layers located between the first electrode and the second electrode, wherein each of the one or more ISM layers comprises:
a layer of hafnium oxide;
a layer of silicon oxide; and
a monolayer of titanium oxide between the layer of hafnium oxide and the layer of silicon oxide.

9. The device of claim 8, wherein the ferroelectric layer is approximately 10 nm thick.

10. The device of claim 8, wherein the ferroelectric layer is located between the first electrode and the one or more ISM layers.

11. The device of claim 8, wherein the one or more ISM layers are located between the ferroelectric layer and the second electrode.

12. The device of claim 8, wherein the one or more ISM layers comprises a plurality of ISM layers.

13. The device of claim 8, wherein the one or more ISM layers comprises three ISM layers.

14. The device of claim 8, wherein the device further comprises connections to a neural network.

15. The device of claim 8, wherein the ferroelectric layer comprises a plurality of ferroelectric dipoles with polarities that are controlled by a voltage applied across the first electrode and the second electrode, and wherein each of the one or more ISM layers comprises material dipoles with polarities that are controlled by the voltage applied across the first electrode and the second electrode.

16. A method of fabricating a ferroelectric device that is enhanced by interface switching modulation, the method comprising:
depositing a first electrode;
depositing a second electrode;
depositing a ferroelectric layer located between the first electrode and the second electrode; and
depositing one or more interface switching modulation (ISM) layers located between the first electrode and the second electrode, wherein each of the one or more ISM layers comprises:
a layer of hafnium oxide;
a layer of silicon oxide; and
a monolayer of titanium oxide between the layer of hafnium oxide and the layer of silicon oxide.

17. The method of claim 16, wherein the first electrode comprises a gate electrode of a ferroelectric transistor.

18. The method of claim 16, wherein the first electrode comprises an electrode of a ferroelectric tunnel junction device.

19. The method of claim 16, wherein the monolayer of titanium oxide is deposited using a deposition process such that the monolayer of titanium oxide comprises titanium ions that have not formed a crystal lattice.

20. The method of claim 16, wherein the layer of hafnium oxide and the layer of silicon oxide generate oxygen ions in the one or more ISM layers, and wherein the layer of titanium oxide generates titanium ions in the one or more ISM layers, such that the oxygen ions and the titanium ions form material dipoles in response to an applied voltage.
